(19) United States
(12) Patent Application Publication
(10) Pub. No.: US 2025/0392099 A1
(43) Pub. Date: Dec. 25, 2025

(54) OPTICAL INTEGRATED LASER DEVICE

(71) Applicants: SUMITOMO ELECTRIC DEVICE INNOVATIONS, INC., Kanagawa (JP); SUMITOMO ELECTRIC INDUSTRIES, LTD., Osaka (JP)

(72) Inventors: Konosuke AOYAMA, Kanagawa (JP); Daisuke INOUE, Osaka (JP)

(73) Assignees: SUMITOMO ELECTRIC DEVICE INNOVATIONS, INC., Kanagawa (JP); SUMITOMO ELECTRIC INDUSTRIES, LTD., Osaka (JP)

(21) Appl. No.: 19/247,141

(22) Filed: Jun. 24, 2025

(30) Foreign Application Priority Data
Jun. 25, 2024 (JP) 2024-102025

(51) Int. Cl. H01S 5/10; H01S 5/028; H01S 5/12

(52) U.S. Cl. CPC H01S 5/1003; H01S 5/028; H01S 5/12

(57) ABSTRACT

An optical integrated laser device includes: an InP substrate; a distributed feedback laser unit having a first optical waveguide being an active region of a laser, and provided on the InP substrate; a semiconductor optical amplifier unit having a second optical waveguide being an active region of the amplifier, and provided on the InP substrate, the second optical waveguide being connected to the first optical waveguide and having a width wider than that of the first optical waveguide; and a highly reflective film having a reflectance of 70% or more, the highly reflective film being provided on an end face of the distributed feedback laser unit opposite to an end face of the semiconductor optical amplifier unit. A length of the second optical waveguide is at least 1.5 times and at most 7 times the length of the first optical waveguide.

### CROSS REFERENCE

Priority is claimed on Japanese Patent Application No. 2024-102025, filed on Jun. 25, 2024, the entire content of which is incorporated herein by reference.

### TECHNICAL FIELD

The present disclosure relates to an optical integrated laser device.

### BACKGROUND

United States Unexamined Patent Publication No. 2012/243074 discloses an optical integrated laser device in which a distributed feedback (DFB) laser and a semiconductor optical amplifier are integrated.

### SUMMARY

An optical integrated laser device according to one embodiment of the present disclosure includes: an InP substrate; a distributed feedback laser unit having a first optical waveguide being an active region of a laser, and provided on the InP substrate; a semiconductor optical amplifier unit having a second optical waveguide being an active region of the amplifier, and provided on the InP substrate, the second optical waveguide being connected to the first optical waveguide and having a width wider than that of the first optical waveguide; and a highly reflective film having a reflectance of 70% or more, the highly reflective film being provided on an end face of the distributed feedback laser unit opposite to an end face of the semiconductor optical amplifier unit. A length of the first optical waveguide is 1000 μm or less. A length of the second optical waveguide is at least 1.5 times and at most 7 times the length of the first optical waveguide.

### BRIEF DESCRIPTION OF THE DRAWINGS

FIG. 1 is a plan view showing an optical integrated laser device according to a first embodiment of the present disclosure.

FIG. 2A is a cross-sectional view taken along line IIa-IIa in FIG. 1.

FIG. 2B is a cross-sectional view taken along line IIb-IIb in FIG. 1.

FIG. 3A is a cross-sectional view taken along line IIIa-IIIa in FIG. 1.

FIG. 3B is a cross-sectional view taken along line IIIb-IIIb in FIG. 1.

FIG. 4A is a cross-sectional view showing a step of a method for manufacturing an optical integrated laser device.

FIG. 4B is a cross-sectional view showing a step of the method for manufacturing an optical integrated laser device.

FIG. 5A is a cross-sectional view showing a step of the method for manufacturing an optical integrated laser device.

FIG. 5B is a cross-sectional view showing a step of the method for manufacturing an optical integrated laser device.

FIG. 6A is a cross-sectional view showing a step of the method for manufacturing an optical integrated laser device.

FIG. 6B is a cross-sectional view showing a step of the method for manufacturing an optical integrated laser device.

FIG. 7A is a cross-sectional view showing a step of the method for manufacturing an optical integrated laser device.

FIG. 7B is a cross-sectional view showing a step of the method for manufacturing an optical integrated laser device.

FIG. 8A is a cross-sectional view showing a step of the method for manufacturing an optical integrated laser device.

FIG. 8B is a cross-sectional view showing a step of the method for manufacturing an optical integrated laser device.

FIG. 9A is a schematic plan view of the optical integrated laser device.

FIG. 9B is a schematic plan view of the optical integrated laser device.

FIG. 10A is a graph showing the relationship between the wavelength of laser light and the normalized threshold gain.

FIG. 10B is a graph showing the relationship between the wavelength of laser light and the light intensity.

FIG. 11A is a view showing how the graph shown in FIG. 10A fluctuates.

FIG. 11B is a view showing how the graph shown in FIG. 10B fluctuates.

FIG. 12A is a view showing how the graph shown in FIG. 10A fluctuates.

FIG. 12B is a view showing how the graph shown in FIG. 10B fluctuates.

FIG. 13 is a plan view showing an optical integrated laser device according to one modification example of the above-described embodiment.

### DETAILED DESCRIPTION

In the optical integrated laser device in which the distributed feedback laser unit and the semiconductor optical amplifier unit are integrated, a highly reflective film is provided on an end face of two end faces of the distributed feedback laser unit, the end face being located on a side opposite the semiconductor optical amplifier unit. Accordingly, the intensity of laser light output from the distributed feedback laser unit can be increased, and as a result, the intensity of the light output from the optical integrated laser device can be increased. However, when the highly reflective film is provided, mode hopping is likely to occur in the distributed feedback laser unit. An object of the present disclosure is to provide an optical integrated laser device capable of increasing the intensity of output laser light while reducing the occurrence of mode hopping.

### Description of Embodiment of Present Disclosure

First, the contents of an embodiment of the present disclosure will be listed and described. [1] An optical integrated laser device according to one embodiment of the present disclosure includes: an InP substrate; a distributed feedback laser unit having a first optical waveguide being an active region of a laser, and provided on the InP substrate; a semiconductor optical amplifier unit having a second optical waveguide being an active region of the amplifier, and provided on the InP substrate, the second optical waveguide being connected to the first optical waveguide and having a width wider than that of the first optical waveguide; and a highly reflective film having a reflectance of 70% or more, the highly reflective film being provided on an end face of the distributed feedback laser unit opposite to an end face of the semiconductor optical amplifier unit. A length of the first optical waveguide is 1000 μm or less. A length of the second optical waveguide is at least 1.5 times and at most 7 times the length of the first optical waveguide.

In the optical integrated laser device according to [1] above, the highly reflective film is provided on the end face of the distributed feedback laser unit opposite to the end face of the semiconductor optical amplifier unit. Accordingly, the intensity of laser light output from the optical integrated laser device can be sufficiently increased. In addition, the length of the second optical waveguide is at least 1.5 times the length of the first optical waveguide. Mode hopping is more likely to occur in the distributed feedback laser unit as the emission intensity of the distributed feedback laser unit increases. Therefore, in order to reduce the occurrence of mode hopping, it is effective to shorten the length of the distributed feedback laser unit and reduce the emission intensity of the distributed feedback laser unit. Furthermore, in order to sufficiently increase the intensity of laser light output from the optical integrated laser device, it is advisable to lengthen the length of the semiconductor optical amplifier unit and increase the gain of the semiconductor optical amplifier unit. By setting the length of the second optical waveguide to at least 1.5 times the length of the first optical waveguide, the intensity of the output laser light can be sufficiently increased while reducing the occurrence of mode hopping. In addition, by setting the length of the second optical waveguide to at most 7 times the length of the first optical waveguide, the first optical waveguide is prevented from becoming too short, and the side mode suppression ratio (SMSR) can be kept at an appropriate value.

[2] In the optical integrated laser device according to [1] above, the length of the second optical waveguide may be at least 2.0 times and at most 3.5 times the length of the first optical waveguide. In this case, the intensity of the output laser light can be further increased while further reducing the occurrence of mode hopping.

[3] In the optical integrated laser device according to [1] above, the length of the second optical waveguide may be at least 2.5 times and at most 3.0 times the length of the first optical waveguide. In this case, the intensity of the output laser light can be further increased while further reducing the occurrence of mode hopping.

[4] In the optical integrated laser device according to any one of [1] to [3] above, the width of the second optical waveguide may be at most 6.5 times the width of the first optical waveguide. In this case, the gain of the semiconductor optical amplifier unit can be further increased. Therefore, the intensity of the output laser light can be further increased.

[5] In the optical integrated laser device according to any one of [1] to [4] above, the second optical waveguide may be inclined with the first optical waveguide. In this case, the intensity of the laser light can be further increased by lengthening the second optical waveguide while shortening the overall length of the optical integrated laser device.

[6] In the optical integrated laser device according to any one of [1] to [5] above, a material of the highly reflective film may be a laminate of one of aluminum oxide, tantalum dioxide, and titanium oxynitride with silicon oxide or titanium oxide.

[7] In the optical integrated laser device according to any one of [1] to [6] above, the highly reflective film may have a reflectance of 90% or more.

### Details of Embodiment of Present Disclosure

A specific example of the present disclosure will be described below with reference to the drawings. The present disclosure is not limited to this example, but is defined by the claims, and is intended to include all modifications within the concept and scope equivalent to the claims. In the following description, the same elements in the description of the drawings are denoted by the same reference signs, and duplicate descriptions will be omitted.

### First Embodiment

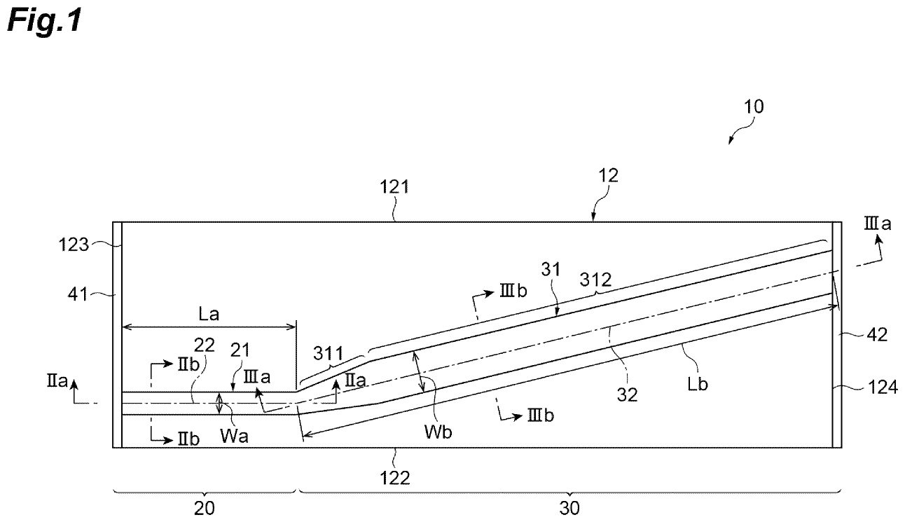

FIG. 1 is a plan view showing an optical integrated laser device 10 according to a first embodiment of the present disclosure. The optical integrated laser device 10 of the present embodiment includes a substrate 12, a distributed feedback laser unit 20, a semiconductor optical amplifier unit 30, a highly reflective film 41, and an anti-reflection film 42. The distributed feedback laser unit 20 and the semiconductor optical amplifier unit 30 are monolithically integrated on the substrate 12. In the optical integrated laser device 10, the distributed feedback laser unit 20 functions as a DFB laser, and the semiconductor optical amplifier unit 30 functions as an SOA.

The substrate 12 is, for example, a semiconductor substrate. In one example, the substrate 12 is an n-type indium phosphide (InP) substrate. The planar shape of the substrate 12 is a rectangular shape. The substrate 12 has a first long side 121 and a second long side 122 extending parallel to each other, and a first short side 123 and a second short side 124 extending parallel to each other and perpendicular to the first long side 121 and the second long side 122. In one example, a length of the substrate 12 in a direction along the first long side 121 and the second long side 122 is 2000 μm or more and 4000 μm or less. As one example, the length is 2500 μm. In addition, a width of the substrate 12 in a direction along the first short side 123 and the second short side 124 is, for example, 400 μm.

The distributed feedback laser unit 20 includes a first optical waveguide 21 provided on the substrate 12. The first optical waveguide 21 is an active region of a laser. The first optical waveguide 21 has a linear optical axis 22. An optical waveguide direction of the first optical waveguide 21 along the optical axis 22 extends parallel to the first long side 121 and the second long side 122. The first optical waveguide 21 is closer to the second long side 122 than to the first long side 121. In order to ensure the stability of laser oscillation, a length La of the first optical waveguide 21 in the optical waveguide direction (the direction along the first long side 121 and the second long side 122) is preferably, for example, 200 μm or more. In addition, as a preferred mode, the length La may be 200 μm or more, 400 μm or more, or 500 μm or more. In addition, the upper limit is 1000 μm or less, and may be 800 μm or less or 650 μm or less as needed.

The semiconductor optical amplifier unit 30 is provided on a first side of the distributed feedback laser unit 20 in the direction along the first long side 121 and the second long side 122. The semiconductor optical amplifier unit 30 includes a second optical waveguide 31 provided on the substrate 12. The second optical waveguide 31 is an active region of an amplifier. The second optical waveguide 31 has a linear optical axis 32. The second optical waveguide 31 is optically connected to the first optical waveguide 21, and has a gain. The second optical waveguide 31 includes a tapered portion 311 and a parallel portion 312. The tapered portion 311 is provided between the first optical waveguide 21 and the parallel portion 312, and connects the parallel portion 312 to the first optical waveguide 21. The parallel portion 312 has a constant width Wb along an optical waveguide direction. The width Wb is wider than a width Wa of the first optical waveguide 21. The width of the tapered portion 311 changes continuously from the width Wa of a first end connected to the first optical waveguide 21 to the width Wb of a second end connected to the parallel portion 312.

The optical waveguide direction of the second optical waveguide 31 along the optical axis 32 is inclined with respect to the optical waveguide direction of the first optical waveguide 21. In the present embodiment, the optical waveguide direction of the second optical waveguide 31 is inclined toward the first long side 121 from the connecting point between the first optical waveguide 21 and the second optical waveguide 31. As described above, under the condition that the length of the substrate 12 in a longitudinal direction is 4000 μm or more, a length Lb of the second optical waveguide 31 in the optical waveguide direction is at least 1.5 times, at least 2.0 times, or at least 2.5 times the length La of the first optical waveguide 21 in the optical waveguide direction. The length Lb of the second optical waveguide 31 in the optical waveguide direction is at most 3.0 times, at most 3.5 times, or at most 7 times the length La of the first optical waveguide 21 in the optical waveguide direction. In one example, when the length of the substrate 12 is set to 2500 μm, the length Lb is 1500 μm or more when the length La is 1000 μm or less. In another example, when the length La is 650 μm or less, the length Lb is 1350 μm or more.

The width Wb of the second optical waveguide 31 is at least 1.0 times and at most 6.5 times the width Wa of the first optical waveguide 21. In one example, the width Wa of the first optical waveguide 21 is a width constituting a single-mode active layer. In one example, Wa is 1.5 μm or more and 3.0 μm or less. The width Wb of the second optical waveguide 31 is 1.5 μm or more and 10.0 μm or less. For example, when the length of the substrate 12 is 2000 μm, the width of the first optical waveguide 21 and the width of the second optical waveguide 31 are 2.0 μm and 5.0 μm, respectively, and when the length of the substrate 12 is 2500 μm, the width of the first optical waveguide 21 and the width of the second optical waveguide 31 are 2.0 μm and 5.5 μm, respectively.

The highly reflective film 41 is provided on an end face on a second side of the distributed feedback laser unit 20, the second side being opposite the first side (semiconductor optical amplifier unit 30 side). The reflectance of the highly reflective film 41 is preferably 70% or more, and more preferably 90% or more. The highly reflective film 41 has, for example, a structure in which one of an aluminum oxide (Al₂O₃), tantalum dioxide (Ta₂O₃) or titanium oxynitride (TiON) layer serving as a high refractive index film and a silicon oxide (SiO₂) or titanium oxide (TiO₂) film serving as a low refractive index film are alternately laminated, and each film is configured with an optically designed thickness.

The anti-reflection film 42 is provided on an end face of the semiconductor optical amplifier unit 30, the end face being located on a side opposite an end face on a distributed feedback laser unit 20 side. The anti-reflection film 42 has, for example, a structure in which one of an aluminum oxide (Al₂O₃) or tantalum dioxide (Ta₂O₃) layer serving as a high refractive index film and a silicon oxide (SiO₂) or titanium oxide (TiO₂) film serving as a low refractive index film are alternately laminated.

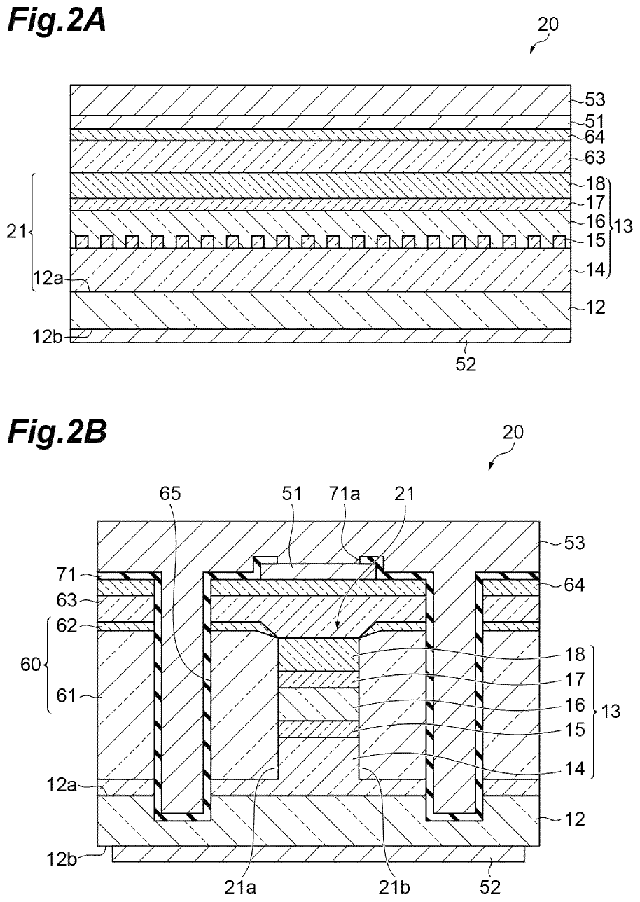

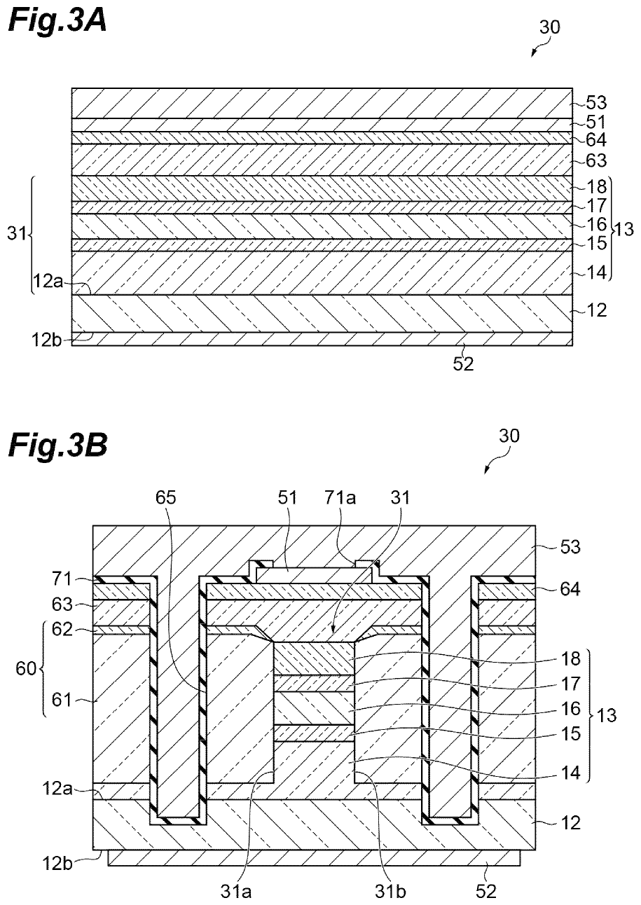

FIG. 2A is a cross-sectional view taken along line IIa-IIa in FIG. 1, and shows a cross section of the distributed feedback laser unit 20 along the optical waveguide direction. FIG. 2B is a cross-sectional view taken along line IIb-IIb in FIG. 1, and shows a cross section of the distributed feedback laser unit 20 perpendicular to the optical waveguide direction. FIG. 3A is a cross-sectional view taken along line IIIa-IIIa in FIG. 1, and shows a cross section of the semiconductor optical amplifier unit 30 along the optical waveguide direction. FIG. 3B is a cross-sectional view taken along line IIIb-IIIb in FIG. 1, and shows a cross section of the semiconductor optical amplifier unit 30 perpendicular to the optical waveguide direction.

As shown in these figures, the optical integrated laser device 10 includes a semiconductor layer 13 provided on a main surface 12a of the substrate 12. The semiconductor layer 13 includes a buffer layer 14, a diffraction grating layer 15, an n-type cladding layer 16, an active layer 17, and a p-type cladding layer 18.

The buffer layer 14 is provided on the substrate 12. The buffer layer 14 is, for example, an n-type InP layer having a thickness of approximately 500 nm. The diffraction grating layer 15 is provided on the buffer layer 14. The diffraction grating layer 15 is, for example, an n-type gallium indium arsenide phosphide (GalnAsP) layer having a thickness of approximately 50 nm. As shown in FIG. 2A, in the distributed feedback laser unit 20, a diffraction grating with a constant period is formed in the diffraction grating layer 15. Meanwhile, as shown in FIG. 3A, in the semiconductor optical amplifier unit 30, no diffraction grating is formed in the diffraction grating layer 15, and the entire upper surface of the buffer layer 14 is covered with the diffraction grating layer 15. The n-type cladding layer 16 is provided on the diffraction grating layer 15 and the buffer layer 14. The n-type cladding layer 16 covers the diffraction grating layer 15. The n-type cladding layer 16 is, for example, an n-type InP layer having a thickness of approximately 500 nm. The active layer 17 is provided on the n-type cladding layer 16. The active layer 17 include a quantum well layer and two barrier layers that sandwiches the quantum well layer therebetween. The quantum well layer is, for example, a GaInAsp layer or an aluminum gallium indium arsenide (AlGaInAs) layer having a thickness of approximately 80 nm. Both the barrier layers are, for example, GaInAsp layers or AlGaInAs layers having a thickness of approximately 30 nm. The active layer 17 is a single-mode active layer having a cross-sectional dimension that allows light to be guided in a single mode. The p-type cladding layer 18 is provided on the active layer 17. The p-type cladding layer 18 is, for example, a p-type InP layer having a thickness of approximately 200 nm.

As shown in FIG. 2B, mesas that become the first optical waveguide 21 and the second optical waveguide 31 are formed in the semiconductor layer 13. The mesa is formed such that a part of the buffer layer 14 is exposed. A height of the mesa is, for example, approximately 1000 nm. The mesa that becomes the first optical waveguide 21 has a first surface 21a and a second surface 21b perpendicular to the main surface 12a. The distance between the first surface 21a and the second surface 21b defines the width Wa described above. The mesa that becomes the second optical waveguide 31 has a third surface 31a and a fourth surface 31b perpendicular to the main surface 12a. The distance between the third surface 31a and the fourth surface 31b defines the width Wb described above.

The semiconductor layer 60 is provided on the sides of each mesa so as to embed the mesa. The semiconductor layer 60 includes a p-type block layer 61 and an n-type block layer 62. The semiconductor layer 60 is in contact with the first surface 21a, the second surface 21b, the third surface 31a, and the fourth surface 31b. At least a part of an upper surface of the p-type cladding layer 18 is exposed from the semiconductor layer 60.

The p-type block layer 61 is provided on the buffer layer 14. The p-type block layer 61 is in contact with the first surface 21a, the second surface 21b, the third surface 31a, and the fourth surface 31b. The p-type block layer 61 is in contact with each side surface of the buffer layer 14, the diffraction grating layer 15, the n-type cladding layer 16, the active layer 17, and the p-type cladding layer 18. The p-type block layer 61 is a p-type InP layer. A thickness of a thickest portion of the p-type block layer 61 is, for example, 1000 nm or more and 1500 nm or less. The n-type block layer 62 is provided on the p-type block layer 61. The n-type block layer 62 is an n-type InP layer. A thickness of a thickest portion of the n-type block layer 62 is, for example, 300 nm or more and 500 nm or less.

The optical integrated laser device 10 further includes a p-type semiconductor layer 63, a contact layer 64, an electrode 51, an electrode 52, a wiring 53, and an insulating film 71.

The p-type semiconductor layer 63 is provided on the p-type cladding layer 18 and the n-type block layer 62. The p-type semiconductor layer 63 is, for example, a p-type InP layer. A thickness of a thickest portion of the p-type semiconductor layer 63 is, for example, 2500 nm or more and 3500 nm or less. The p-type semiconductor layer 63 can function as a part of the p-type cladding layer 18.

The contact layer 64 is provided on the p-type semiconductor layer 63. The contact layer 64 includes a p-type GaInAsP layer and a p-type indium gallium arsenide (InGaAs) layer. The GaInAsP layer is provided on the p-type semiconductor layer 63. A thickness of the GaInAsP layer is, for example, approximately 200 nm. The InGaAs layer is provided on the GaInAsP layer. A thickness of the InGaAs layer is, for example, approximately 300 nm. A band gap of the contact layer 64 is smaller than a band gap of the p-type semiconductor layer 63. The electrode 51 is provided on the contact layer 64. The electrode 51 is provided to overlap the mesas in a plan view. Namely, the contours of the mesas are located inside the contour of the electrode 51 in a plan view.

Two trenches 65 are formed in a laminate including the substrate 12, the buffer layer 14, the semiconductor layer 60, the p-type semiconductor layer 63, and the contact layer 64. The two trenches 65 are formed to sandwich the mesas therebetween. The two trenches 65 extend along the mesas.

The insulating film 71 covers an upper surface of the contact layer 64, an upper surface and a side surface of the electrode 51, and inner wall surfaces and bottom surfaces of the trenches 65. The insulating film 71 is, for example, a silicon oxide (SiO₂) film, a silicon oxynitride (SiON) film, or a silicon nitride (SiN) film. An opening portion 71a that exposes a part of the upper surface of the electrode 51 is formed in the insulating film 71.

The wiring 53 is provided on the insulating film 71. The wiring 53 is also provided inside the trenches 65. The wiring 53 is in contact with the electrode 51 at the opening portion 71a. The wiring 53 is, for example, a gold (Au) wiring. The electrode 52 is provided on a back surface 12b of the substrate 12. The electrode 52 is in contact with the substrate 12. The contact layer 64, the electrode 51, and the wiring 53 are electrically insulated and separated between the distributed feedback laser unit 20 and the semiconductor optical amplifier unit 30, and independent voltages can be applied to the distributed feedback laser unit 20 and the semiconductor optical amplifier unit 30.

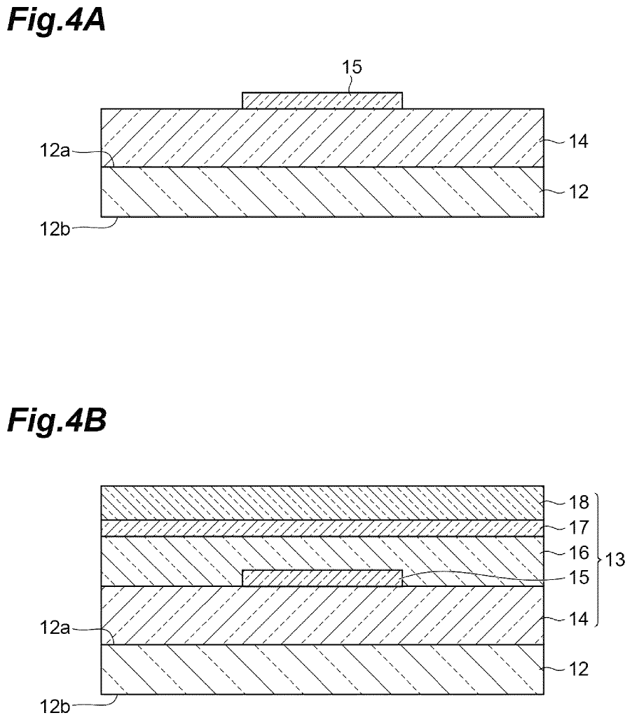

Next, a method for manufacturing the optical integrated laser device 10 according to the first embodiment will be described. FIGS. 4A to 8B are cross-sectional views showing the method for manufacturing the optical integrated laser device 10, and show cross sections perpendicular to the optical waveguide direction.

First, as shown in FIG. 4A, the substrate 12 having the main surface 12a and the back surface 12b is prepared, and the buffer layer 14 is formed on the main surface 12a. Next, the diffraction grating layer 15 is formed on the buffer layer 14. The diffraction grating layer 15 may be formed wider than its final dimensions. In a portion included in the distributed feedback laser unit 20, a diffraction grating is formed in the diffraction grating layer 15 (see FIG. 2A), and in a portion included in the semiconductor optical amplifier unit 30, the entire upper surface of the buffer layer 14 is covered with the diffraction grating layer 15.

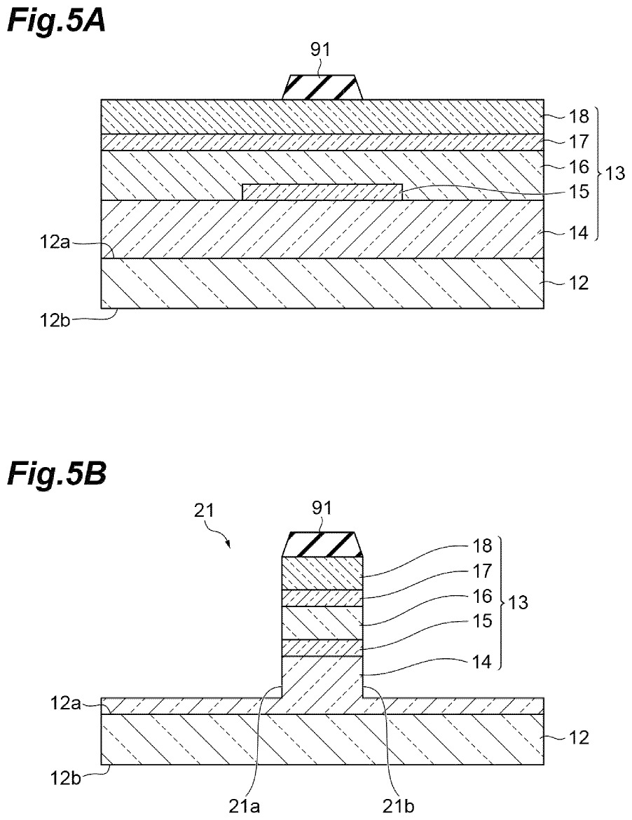

Next, as shown in FIG. 4B, the n-type cladding layer 16 is formed on the diffraction grating layer 15 and the buffer layer 14. The n-type cladding layer 16 covers the diffraction grating layer 15. Next, the active layer 17 is formed on the n-type cladding layer 16, and the p-type cladding layer 18 is formed on the active layer 17. Next, as shown in FIG. 5A, a mask 91 is formed on the p-type cladding layer 18. The mask 91 is formed on regions that become mesas. The mask 91 is, for example, an SiO₂ film.

Next, as shown in FIG. 5B, dry etching is performed on the p-type cladding layer 18, the active layer 17, the n-type cladding layer 16, and the diffraction grating layer 15, and a part of the buffer layer 14 using the mask 91 as an etching mask. As a result, mesas that become the first optical waveguide 21 and the second optical waveguide 31 are formed. The dry etching is, for example, reactive ion etching (RIE) using silicon tetrachloride (SiCl₄).

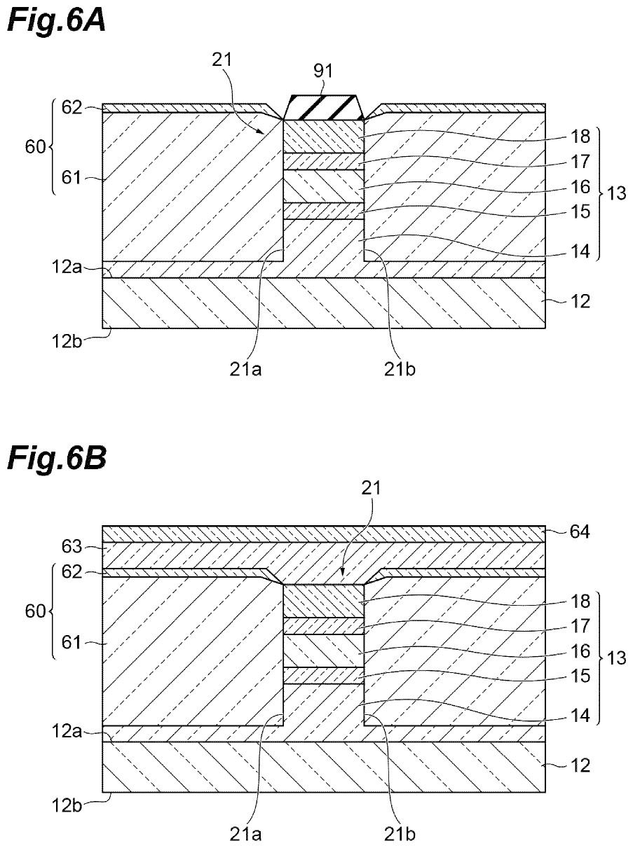

Next, as shown in FIG. 6A, using the mask 91 as a selective growth mask, the p-type block layer 61 is formed on the buffer layer 14 exposed from the mesas, and the n-type block layer 62 is formed on the p-type block layer 61. As a result, the mesas are embedded in the semiconductor layer 60 including the p-type block layer 61 and the n-type block layer 62.

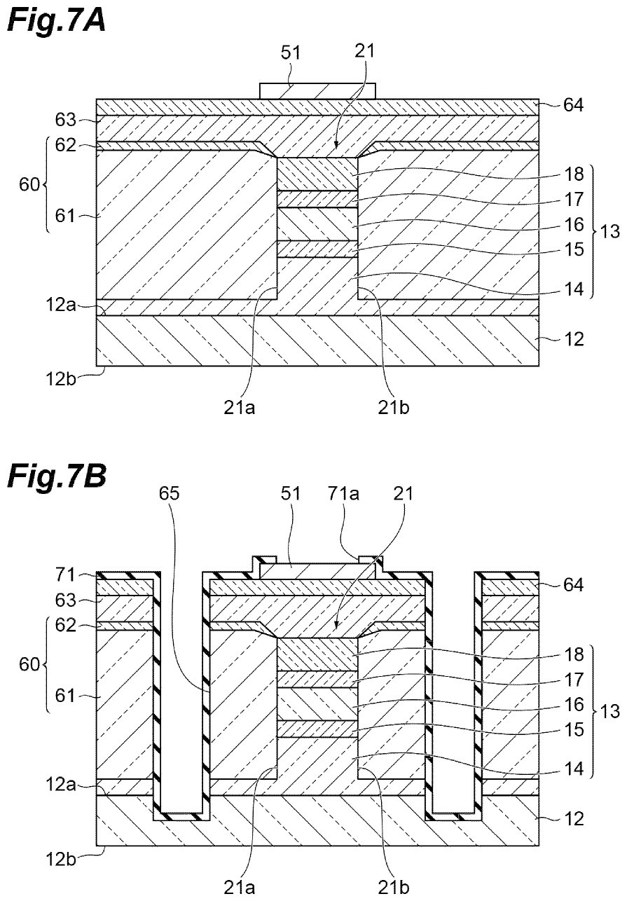

Next, as shown in FIG. 6B, the mask 91 is removed. The mask 91 can be removed using, for example, hydrofluoric acid (HF). Next, the p-type semiconductor layer 63 is formed on the p-type cladding layer 18 and the n-type block layer 62, and the contact layer 64 is formed on the p-type semiconductor layer 63. The p-type semiconductor layer 63 is integrated with the p-type cladding layer 18. Next, as shown in FIG. 7A, the electrode 51 is formed on the contact layer 64.

Next, as shown in FIG. 7B, two trenches 65 are formed in a laminate including the substrate 12, the buffer layer 14, the semiconductor layer 60, the p-type semiconductor layer 63, and the contact layer 64. The trenches 65 are formed, for example, by dry etching using an etching mask (not shown). The dry etching is, for example, RIE using SiCl₄. Next, the insulating film 71 covering the upper surface of the contact layer 64, the upper surface and the side surfaces of the electrode 51, and the inner wall surfaces and the bottom surfaces of the trenches 65 is formed, and the opening portion 71a that exposes a part of the upper surface of the electrode 51 is formed in the insulating film 71.

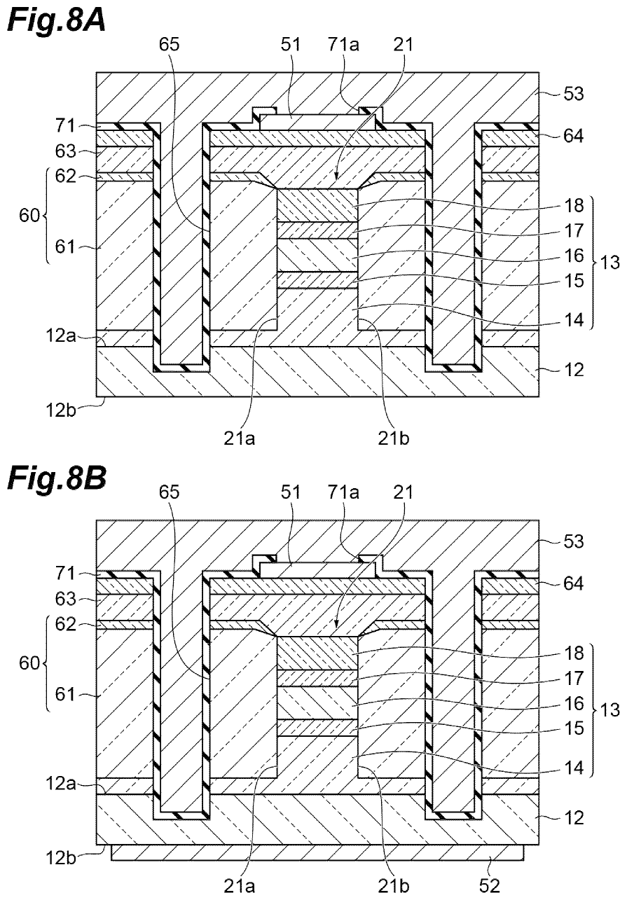

Next, as shown in FIG. 8A, the wiring 53 is formed on the insulating film 71. The wiring 53 is also formed inside the trenches 65. The wiring 53 is in contact with the electrode 51. Next, as shown in FIG. 8B, the substrate 12 is polished from the back surface 12b. Next, the electrode 52 in contact with the substrate 12 is formed on the back surface 12b. The distributed feedback laser unit 20 and the semiconductor optical amplifier unit 30 are formed through the above steps. Next, the highly reflective film 41 covering the end face of the distributed feedback laser unit 20 and the anti-reflection film 42 covering the end face of the semiconductor optical amplifier unit 30 are formed. The optical integrated laser device 10 according to the present embodiment is produced through the above steps.

In the optical integrated laser device 10, when a voltage is applied between the electrode 51 and the electrode 52 in the distributed feedback laser unit 20, light is generated in the active layer 17, and the light resonates in the first optical waveguide 21 to become laser light. At this time, the central wavelength of the laser light is determined by the action of the diffraction grating. The laser light is amplified by the semiconductor optical amplifier unit 30, and is output to the outside of the optical integrated laser device 10 through the anti-reflection film 42. Since the optical axis 32 of the semiconductor optical amplifier unit 30 is inclined with respect to the optical axis 22 of the distributed feedback laser unit 20, a traveling direction of the laser light in the semiconductor optical amplifier unit 30 is different from a traveling direction of the laser light in the distributed feedback laser unit 20. However, since the semiconductor layer 60 is provided, the laser light is confined inside the mesas, and leakage of the laser light to the outside of the mesas is reduced.

Effects obtained by the optical integrated laser device 10 according to the present embodiment described above will be described. In the optical integrated laser device 10 of the present embodiment, the highly reflective film 41 is provided on the end face on the second side of the distributed feedback laser unit 20, the second side being opposite the first side. Accordingly, the intensity of the laser light output from the optical integrated laser device 10 can be sufficiently increased.

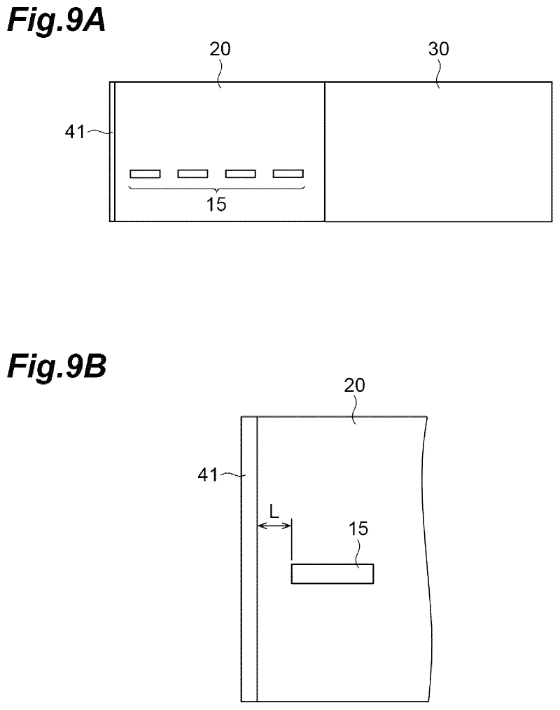

However, the following problems occur due to the highly reflective film 41 (here, the reflectance of the highly reflective film 41 is 70% or more) being provided. FIG. 9A is a schematic plan view of the optical integrated laser device 10, and FIG. 9B is a partial enlarged view of the optical integrated laser device 10. The end face of the distributed feedback laser unit 20 is formed by dicing. Since the accuracy of dicing is low, the position of the highly reflective film 41 of the distributed feedback laser unit 20 in the optical waveguide direction varies within a range of approximately ±10 μm. Meanwhile, one period of the diffraction grating is approximately 200 nm. Therefore, a distance L between an end of the diffraction grating and the highly reflective film 41 is randomly determined. As a result, the time it takes for the laser light to reflect off the highly reflective film 41 and return is random, and a slight time deviation caused thereby significantly affects the oscillation mode of the laser light.

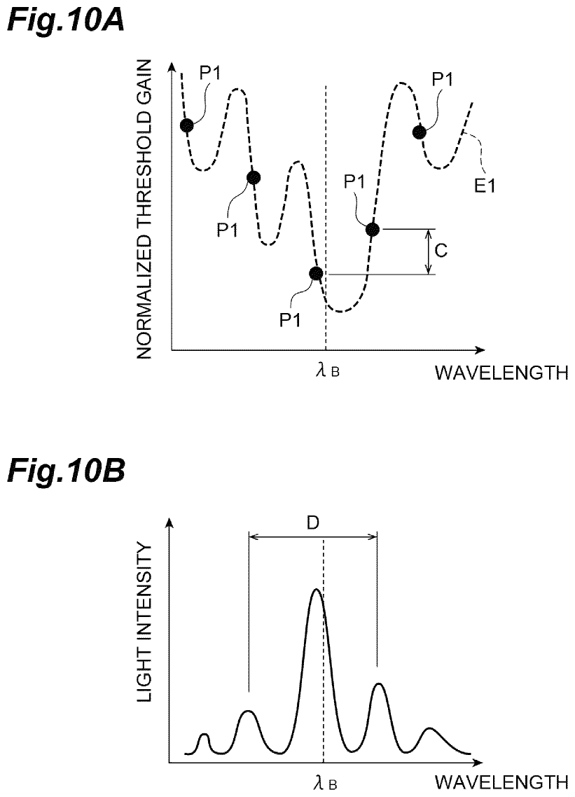

FIG. 10A is a graph showing the relationship between the wavelength of the laser light and the normalized threshold gain («L). FIG. 10B is a graph showing the relationship between the wavelength of the laser light and the light intensity. In the figure, λ_{B} is the Bragg wavelength determined by the period of the diffraction grating, and D is the stop band width. As shown in FIG. 10A, the normalized threshold gain fluctuates with the wavelength of the laser light. Furthermore, a plurality of oscillation modes P1 exist discretely on a fluctuation curve E1. The peak wavelength of the laser light is determined depending on which of the plurality of oscillation modes P1 the laser light oscillates in. FIG. 10B shows, as an example, a case in which the laser light oscillates in the oscillation mode P1 in which the normalized threshold gain is at its minimum. A normalized threshold gain difference (oscillation mode gain difference) C exits between each oscillation mode P1 and the adjacent oscillation mode P1.

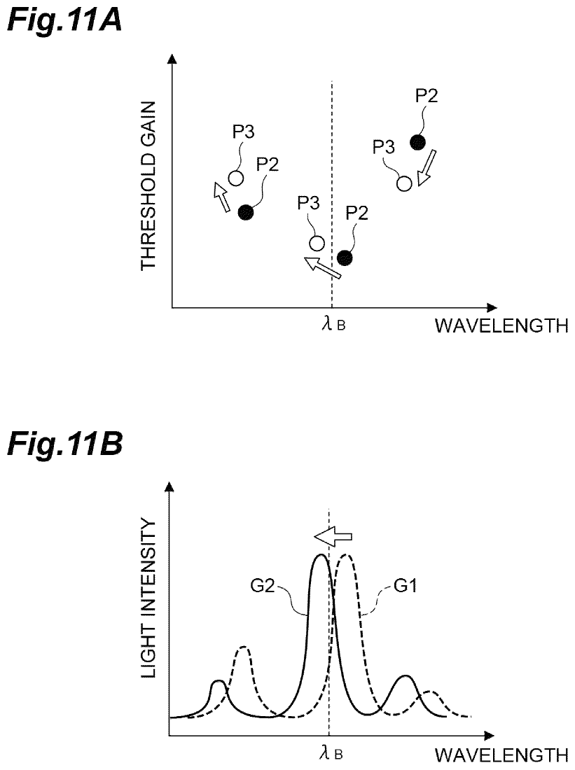

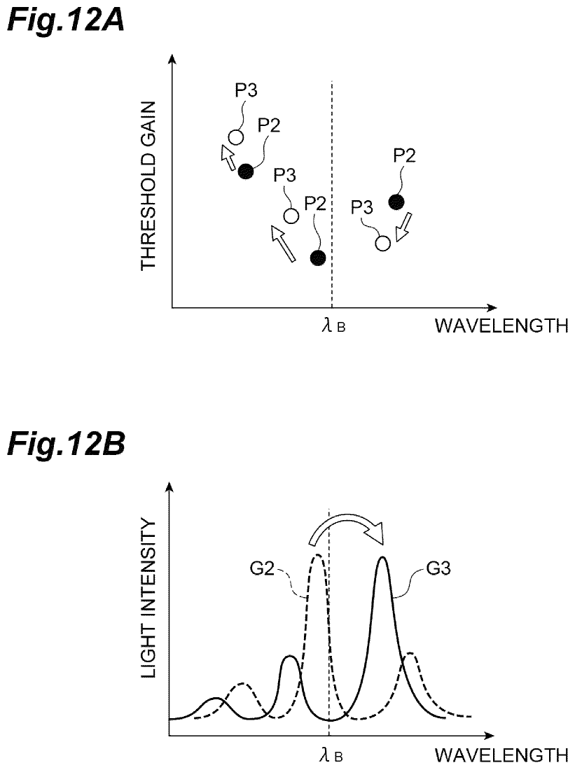

FIGS. 11A and 12A are views showing how the graphs shown in FIG. 10A fluctuates. FIGS. 11B and 12B are views showing how the graphs shown in FIG. 10B fluctuates. When the emission intensity inside the distributed feedback laser unit 20, the current flowing through the distributed feedback laser unit 20, or the temperature of the distributed feedback laser unit 20 changes, the wavelength of each oscillation mode and the threshold gain change as shown in FIG. 11A. In the figure, point P2 represents an oscillation mode before the change, and point P3 represents an oscillation mode after the change. Furthermore, the relationship between the wavelength of the laser light and the light intensity also changes in accordance with the change in the oscillation mode as shown in FIG. 11B. In the figure, curve G1 represents a relationship before the change, and curve G2 represents a relationship after the change.

However, when the change in the emission intensity of the distributed feedback laser unit 20, the change in current, or the change in temperature increases, the amount of change in the wavelength of each oscillation mode and the threshold gain also increases as shown in FIG. 12A. As a result, a phenomenon in which each oscillation mode changes instantaneously to the adjacent oscillation mode occurs. Such a phenomenon is referred to as mode hopping. Due to this mode hopping, as shown in FIG. 12B, the peak wavelength of the laser light also changes instantaneously to a wavelength corresponding to the adjacent oscillation mode. Therefore, when mode hopping occurs frequently, the peak wavelength of the laser light output from the optical integrated laser device 10 becomes unstable.

Mode hopping is more likely to occur in the distributed feedback laser unit 20 as the emission intensity of the distributed feedback laser unit 20 increases. The reason is that, as shown in FIG. 11A, the amount of fluctuation in the oscillation mode threshold gain becomes more remarkable as the amount of fluctuation in the emission intensity increases. As the length La becomes longer, the emission intensity of the distributed feedback laser unit 20 increases, and therefore, the oscillation mode gain fluctuation increases, so that the oscillation mode is likely to transition to a different oscillation mode. Therefore, in order to reduce the occurrence of mode hopping and stabilize the peak wavelength of the laser light, it is effective to reduce the amount of fluctuation in the oscillation mode gain by shortening the length La of the distributed feedback laser unit 20 in the optical waveguide direction. The occurrence of mode hopping can be reduced by setting the length La of the first optical waveguide 21 in the optical waveguide direction to 1000 μm or less, the first optical waveguide 21 constituting a single-mode active layer lattice-matched to the InP substrate. Since the occurrence of mode hopping can be reduced, the peak wavelength of the laser light can be stabilized. However, since the emission intensity of the distributed feedback laser unit 20 is dependent on the length La, when the length La becomes shorter, the emission intensity of the distributed feedback laser unit 20 also decreases.

Therefore, in order to sufficiently increase the intensity of the laser light output from the optical integrated laser device 10, the length Lb of the second optical waveguide 31 in the optical waveguide direction is lengthened, and the gain of the semiconductor optical amplifier unit 30 is increased. In the present embodiment, by setting the length Lb of the second optical waveguide 31 in the optical waveguide direction to at least 1.5 times the length La of the first optical waveguide 21 in the optical waveguide direction, the intensity of the output laser light can be sufficiently increased while reducing the occurrence of mode hopping. Namely, regarding the problem that mode hopping is likely to occur due to the highly reflective film 41 being provided on the end face on the second side, mode hopping is suppressed by setting the length La of the optical waveguide (first optical waveguide 21) of the distributed feedback laser unit in the optical waveguide direction to 1000 μm or less, the distributed feedback laser unit being composed of a single-mode active layer that is lattice-matched to the InP substrate, while the gain of the semiconductor optical amplifier unit 30 is ensured and the insufficient light output is compensated for by setting the length Lb of the second optical waveguide 31 in the optical waveguide direction to at least 1.5 times the length La of the first optical waveguide 21 in the optical waveguide direction.

In addition, as in the present embodiment, the length Lb of the second optical waveguide 31 in the optical waveguide direction may be at most 7 times the length La of the first optical waveguide 21 in the optical waveguide direction. Accordingly, the first optical waveguide 21 is prevented from becoming too short, and the side mode suppression ratio (SMSR) can be kept at an appropriate value.

The length Lb of the second optical waveguide 31 in the optical waveguide direction may be at least 2.0 times the length La of the first optical waveguide 21 in the optical waveguide direction. In this case, the intensity of the output laser light can be further increased while further reducing the occurrence of mode hopping.

As in the present embodiment, the width of the second optical waveguide 31 may be at least 1.0 times and at most 6.5 times the width of the first optical waveguide 21. In this case, the gain of the semiconductor optical amplifier unit 30 can be further increased. Therefore, the intensity of the output laser light can be further increased.

As in the present embodiment, the optical waveguide direction of the second optical waveguide 31 may be inclined with respect to the optical waveguide direction of the first optical waveguide 21. In this case, the intensity of the laser light can be further increased by lengthening the second optical waveguide 31 while shortening the overall length of the optical integrated laser device 10.

As in the present embodiment, the planar shape of the substrate 12 may be a rectangular shape having the second long side 122 and the first long side 121 extending parallel to each other. The optical waveguide direction of the first optical waveguide 21 may extend parallel to the second long side 122 and the first long side 121. The first optical waveguide 21 may be closer to the second long side 122 than to the first long side 121. The optical waveguide direction of the second optical waveguide 31 may be inclined toward the first long side 121 from the connecting point between the first optical waveguide 21 and the second optical waveguide 31. In this case, the intensity of the laser light can be further increased by lengthening the second optical waveguide 31 while avoiding an increase in the width of the optical integrated laser device 10.

As in the present embodiment, the length La of the first optical waveguide 21 in the optical waveguide direction may be 1000 μm or less. In this case, the occurrence of mode hopping can be effectively reduced. In addition, the length La of the first optical waveguide 21 in the optical waveguide direction may be 300 μm or more. In this case, the SMSR can be kept at an appropriate value.

### Modification Example

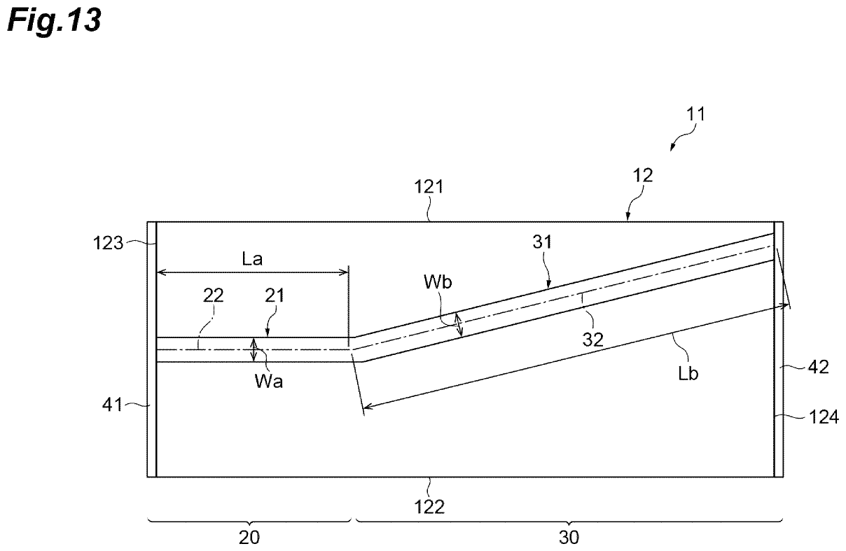

FIG. 13 is a plan view showing an optical integrated laser device 11 according to one modification example of the above-described embodiment. The optical integrated laser device 11 differs from that in the above-described embodiment in that the width Wb of the second optical waveguide 31 is the same as the width Wa of the first optical waveguide 21, and is the same as that in the above-described embodiment in other respects. Even in such a mode, the same effects as those in the above-described embodiment can be obtained.

The optical integrated laser device according to the present disclosure is not limited to the embodiment described above, and can be modified in other various forms. For example, in the above-described embodiment, an example in which the optical waveguide direction of the second optical waveguide is inclined with respect to the optical waveguide direction of the first optical waveguide has been described; however, the optical waveguide direction of the second optical waveguide may coincide with the optical waveguide direction of the first optical waveguide.

What is claimed is:

1. An optical integrated laser device, comprising:
an InP substrate;
a distributed feedback laser unit having a first optical waveguide being an active region of a laser, and provided on the InP substrate;
a semiconductor optical amplifier unit having a second optical waveguide being an active region of an amplifier, and provided on the InP substrate, the second optical waveguide being connected to the first optical waveguide and having a width wider than that of the first optical waveguide; and
a highly reflective film having a reflectance of 70% or more, the highly reflective film being provided on an end face of the distributed feedback laser unit opposite to an end face of the semiconductor optical amplifier unit,
wherein a length of the first optical waveguide is 1000 μm or less, and a length of the second optical waveguide is at least 1.5 times and at most 7 times the length of the first optical waveguide.

2. The optical integrated laser device according to claim 1,
wherein the length of the second optical waveguide is at least 2 times and at most 3.5 times the length of the first optical waveguide.

3. The optical integrated laser device according to claim 1,
wherein the length of the second optical waveguide is at least 2.5 times and at most 3 times the length of the first optical waveguide.

4. The optical integrated laser device according to claim 1,
wherein the width of the second optical waveguide is at most 6.5 times the width of the first optical waveguide.

5. The optical integrated laser device according to claim 1,
wherein the second optical waveguide is inclined with the first optical waveguide.

6. The optical integrated laser device according to claim 1,
wherein a material of the highly reflective film is a laminate of one of aluminum oxide, tantalum dioxide, and titanium oxynitride with silicon oxide or titanium oxide.

7. The optical integrated laser device according to claim 1,
wherein the highly reflective film has a reflectance of 90% or more.
